(19) United States
(12) Patent Application Publication
(10) Pub. No.: US 2015/0349155 A1
(43) Pub. Date: Dec. 3, 2015

(54) FOIL-BASED METALLIZATION OF SOLAR CELLS

(71) Applicants: Taeseok Kim, San Jose, CA (US); Thomas P. Pass, San Jose, CA (US)

(72) Inventors: Taeseok Kim, San Jose, CA (US); Thomas P. Pass, San Jose, CA (US)

(21) Appl. No.: 14/292,571

(22) Filed: May 30, 2014

(51) Int. Cl. H01L 31/0224; H01L 31/18

(52) U.S. Cl. CPC H01L 31/022433; H01L 31/18

(57) ABSTRACT

A solar cell can include a semiconductor region disposed in or above a substrate. The solar cell can also include a contact finger formed over the semiconductor region, where a first weld region couples the contact finger to the semiconductor region. The contact finger can include a first relief structure.

### BACKGROUND

Photovoltaic (PV) cells, commonly known as solar cells, are well known devices for conversion of solar radiation into electrical energy. Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to the conductive regions on the solar cell to direct an electrical current from the cell to an external circuit. When PV cells are combined in an array such as a PV module, the electrical energy collect from all of the PV cells can be combined in series and parallel arrangements to provide power with a certain voltage and current.

Solar cell metallization processes are used in solar cell fabrication to create metal contact regions, such as contact fingers, which allow for the conduction of electricity from doped semiconductor regions of the solar cell to an external circuit. Accordingly, techniques for increasing the efficiency in the fabrication of solar cells, are generally desirable. Various examples are provided throughout.

### BRIEF DESCRIPTION OF THE DRAWINGS

FIG. 1 illustrates a cross-sectional view of a stage in solar cell fabrication during the formation of a weld region, according to some embodiments.

FIG. 2 illustrates cross-sectional view of a solar cell after the formation of a weld region, according to some embodiments.

FIG. 3 illustrates a flow chart representation of a method of metallization for a solar cell, according to some embodiments.

FIG. 4 illustrates a cross-sectional view of a stage in solar cell fabrication during the formation of a weld region, according to some embodiments.

FIG. 5 illustrates cross-sectional view of a solar cell after the formation of a weld region, according to some embodiments.

FIG. 6 illustrates a flow chart representation of another method of metallization for a solar cell, according to some embodiments.

FIGS. 7-10 illustrate cross-sectional views of various stages in the fabrication of a solar cell using foil-based metallization, according to some embodiments.

FIGS. 11-14 illustrate example solar cells, according to some embodiments.

FIG. 15 illustrates a schematic plan view of a conductive foil in accordance with the presented method of FIG. 6.

FIG. 16 illustrates a schematic plan view of a solar cell, according to some embodiments.

FIG. 17 illustrates a schematic plan view of another solar cell, according to some embodiments.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, a relief groove is a structure that can provide relief to a substrate from thermal stress and distortion. A reference to a “first” relief groove does not necessarily imply that this relief groove is the first relief groove in a sequence; instead the term “first” is used to differentiate this relief groove from another relief groove (e.g., a “second” relief groove).

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

“Adjacent”—As used herein, adjacent is used to describe one component being next to or beside another component. Additionally, “adjacent” can also refer to the position of a component within a distance to another component.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present disclosure.

Solar cell metallization processes are used in solar cell fabrication to create metal contact regions, such as contact fingers, which allow for the conduction of electricity from doped semiconductor regions of the solar cell to an external circuit. Solar cell metallization processes can include the formation of weld regions which allow for electrical and mechanical coupling of conductive regions of a solar cell. This specification describes an example solar cell metallization process, methods for forming relief structures to provide stress relief during the solar cell metallization process, followed by example solar cells having said relief structures. Various examples are provided throughout.

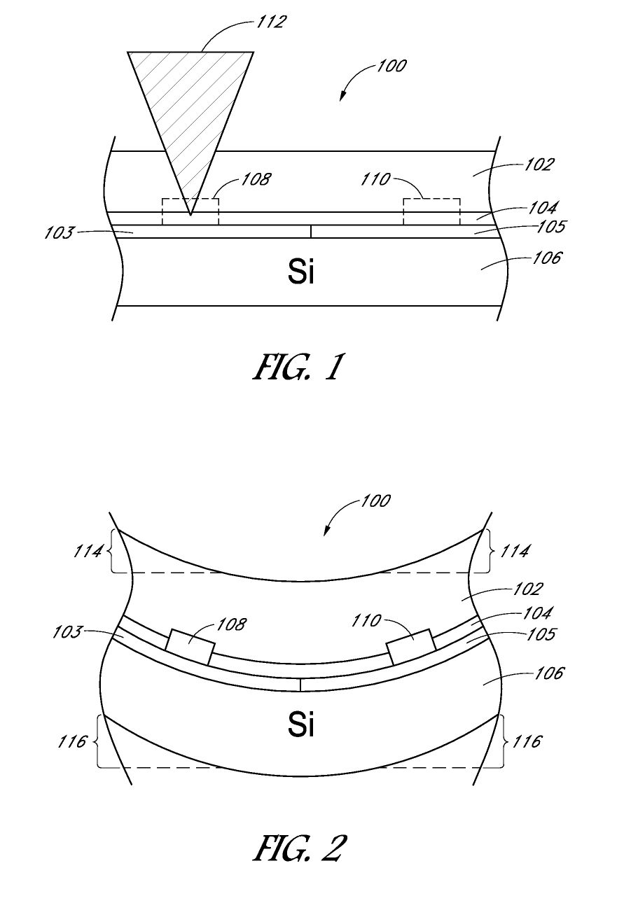

Turning now to FIG. 1, the formation of a weld region in a solar cell is shown. The solar cell 100 can include a substrate 106. In an embodiment, the substrate 106 can be a silicon substrate. The solar cell 100 can also include semiconductor regions 103, 105. In some embodiments the semiconductor regions 103, 105 can include a P-type doped semiconductor region 103 and an N-type doped semiconductor region 105. A conductive region 104 can be formed over the semiconductor regions 103, 105. A conductive foil 102 can be formed over the conductive region 104. First and second weld regions 108, 110 can be formed which allow for conduction of electricity between the semiconductor region, conductive region and conductive foil.

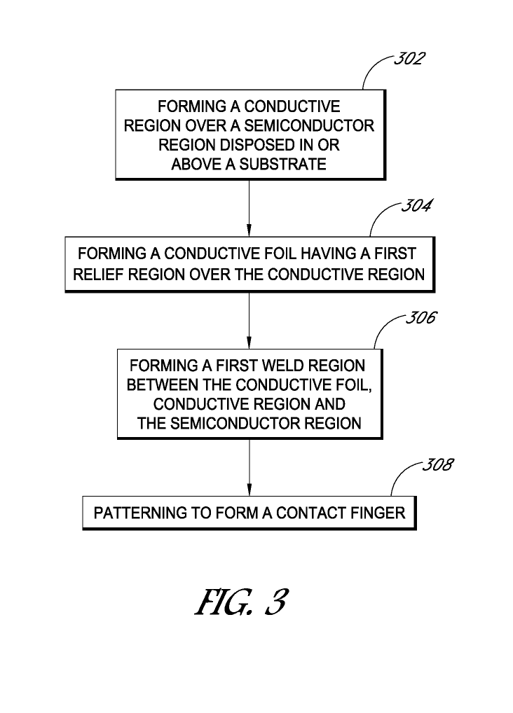

FIG. 2 illustrates the effect of thermal stress on the solar cell. An unwanted result from the welding process on a conductive foil 102 can be the build-up of thermal stress at the conductive foil 102 during the formation of the welding regions 108, 110. This thermal stress or distortion can cause the solar cell 100 to curve or bow 114, 116 as shown. The bowing effect 114, 116 can be detrimental to the solar cell 100. In an example, the bowed shaped of the solar cell can make the solar cell more susceptible to cracking. In another example, planer solar cells (e.g., non-curved or without bowing) are desirable for wafer handling and in a pattern alignment step.

FIG. 3 illustrates a flow chart for a method of metallization for a solar cell, according to some embodiments. In various embodiments, the method of FIG. 3 can include additional (or fewer) blocks than illustrated. For example, in some embodiments, forming a conductive region at block 302 may not be performed or (instead) a conductive foil may be formed directly over the semiconductor region at 304.

As shown in 302, a conductive region can be formed over a semiconductor region disposed in or above a substrate. In an embodiment, the substrate can be a silicon substrate. In some embodiments, the semiconductor region is a polysilicon region. For example, in one embodiment, the first conductive region can be formed as a continuous, blanket deposition of metal. Deposition techniques can include sputtered, evaporated, or otherwise blanket deposited conductive material. In an embodiment, the conductive region can be a printed metal seed region. In an example, forming the conductive region can include forming copper, tin, tungsten, titanium, titanium tungsten, silver, gold, titanium nitride, tantalum nitride, ruthenium, platinum, aluminum and aluminum alloys over the semiconductor region.

At 304, a conductive foil having one or more relief regions can be formed over the conductive region. In an embodiment, the first relief region can be an extrusion of the conductive foil. In an embodiment, forming the conductive foil can include placing/applying an aluminum and/or an aluminum alloy foil over the conductive region. In some embodiments, forming the conductive region can include forming an aluminum and/or aluminum alloy foil directly over the semiconductor region (e.g., without an intervening conductive region between the foil and semiconductor region). In various embodiments, conductive foil can include aluminum, copper, tin, other conductive materials, and/or a combination thereof.

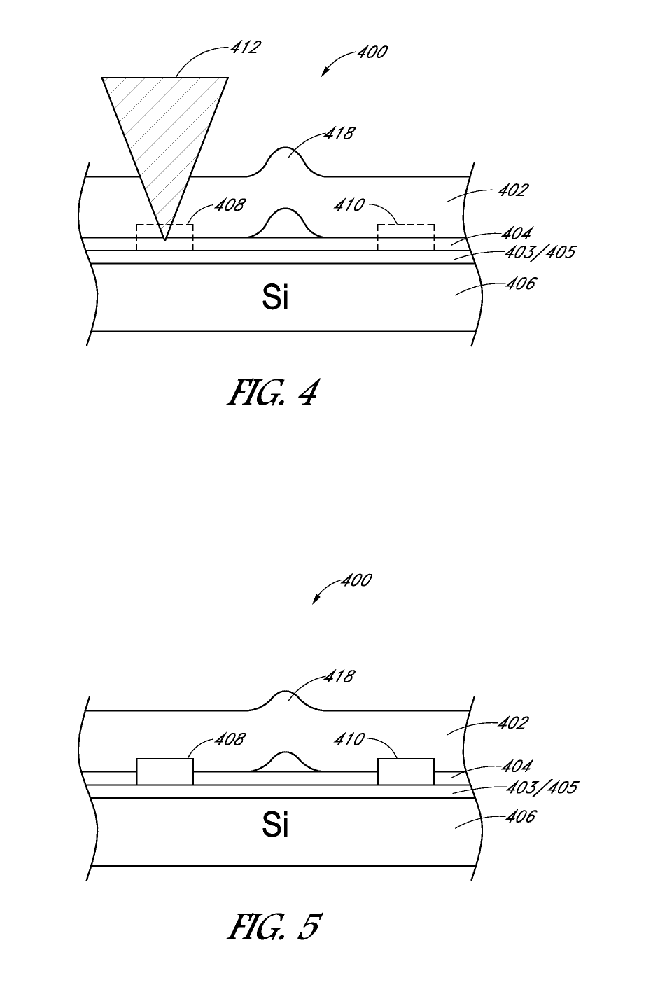

At 306, a first weld region can be formed between the conductive foil and the conductive region and/or semiconductor region. In an embodiment, a laser can be used to form the first weld region. In one embodiment, multiple weld regions can be formed. In some embodiments, the first relief region can positioned between weld regions. FIG. 4 shows an example of the process of forming weld regions, where a first relief region can be positioned between the weld regions. FIG. 5 shows an example solar cell subsequent to the welding process, according to some embodiments. The first relief region can release tensile stress of the conductive foil and/or any compressive stress on the substrate, and thus inhibit the effect of thermal distortion on the solar cell during the welding process.

At 308, a patterning process can be performed to form a contact finger. In an embodiment, patterning to form a contact finger can include a grooving process. An example grooving process can include using a laser to form opposite polarity contact fingers from the conductive foil. In an example, a grooving process can include scribing, scratching or denting locations on the conductive foil. In some embodiments, the patterning process can include an etching process (e.g., chemical etch). In other embodiments, the patterning process can include both grooving and etching processes, performed together or in separate stages. In an embodiment, the first weld region can couple the contact finger to the semiconductor region. In an embodiment, forming the contact finger can include forming a contact finger comprised of aluminum or aluminum alloys or other conductive materials.

In another embodiment, a conductive foil without a first relief region can be used, where the conductive region and the conductive foil can be pre-heated before forming a first weld region, at 306, and the patterning, at 308. The preheating steps can reduce residual stress build up during melting and cooling of the welding region and its surroundings and thus reduce or eliminate the effect of thermal distortion on the solar cell during the welding process. In another example, post mechanical processing like peening can be performed to release the residual tensile stress. In one example, mechanical processing (e.g., hammering) can be performed to balance the tensile stress at the laser welded region.

FIGS. 4 and 5 illustrate cross-sectional views of forming a weld region on a solar cell. Unless otherwise specified below, the numerical indicators used to refer to components in FIGS. 4 and 5 are similar to those used to refer to components or features in FIGS. 1 and 2.

With reference to FIG. 4, an example for forming weld regions 408, 410 on a solar cell 400 is shown. The solar cell 400 can include a substrate 406. In an embodiment, the substrate 406 can be a silicon substrate. In an embodiment, the silicon substrate 406 can be single-crystalline or multi-crystalline silicon. The solar cell 400 can also include semiconductor regions 403/405. In some embodiments the semiconductor regions 403/405 can include a P-type doped semiconductor region 403 and an N-type doped semiconductor region 405. In some embodiments, the substrate 406 can be cleaned, polished, planarized, and/or thinned or otherwise processed before the formation of semiconductor regions 403/405.

In an embodiment, the solar cell 400 can be provided with conductive foil 402 having a first relief region 418, semiconductor regions 403/405 formed over the substrate 406 and a conductive region 404 formed between the conductive foil 402 and the semiconductor regions 403/405. In an embodiment, the first relief region 418 can be an extrusion of the conductive foil 402. In an example, the conductive region can include one or more of copper, tin, tungsten, titanium, titanium tungsten, silver, gold, titanium nitride, tantalum nitride, ruthenium, platinum, aluminum and aluminum alloys. In some embodiments, the conductive foil 402 can include aluminum, aluminum alloy, copper, nickel, tin, and/or alloys of any of those materials, among other examples. In an embodiment, the conductive foil 404 can be formed directly over the semiconductor region 403/405. Although illustrated in FIG. 4 as a single relief region, in some embodiments, the conductive foil 402 can include multiple relief regions.

In an embodiment, a laser 412 can be used to form a first weld region 408. In one embodiment, multiple weld regions 408, 410 can be formed.

FIG. 5 illustrates the solar cell subsequent to the welding process of FIG. 4. In an embodiment, the first relief region 418 can be positioned between weld regions 408, 410. The first relief region 418 can release tensile stress of the conductive foil and/or any compressive stress on the substrate 406. Thus, the first relief region 418 can inhibit the effect of thermal distortion on the solar cell 400 during the welding process. The first relief region 418 can also reduce stress between the conductive foil 402 and the conductive region 404.

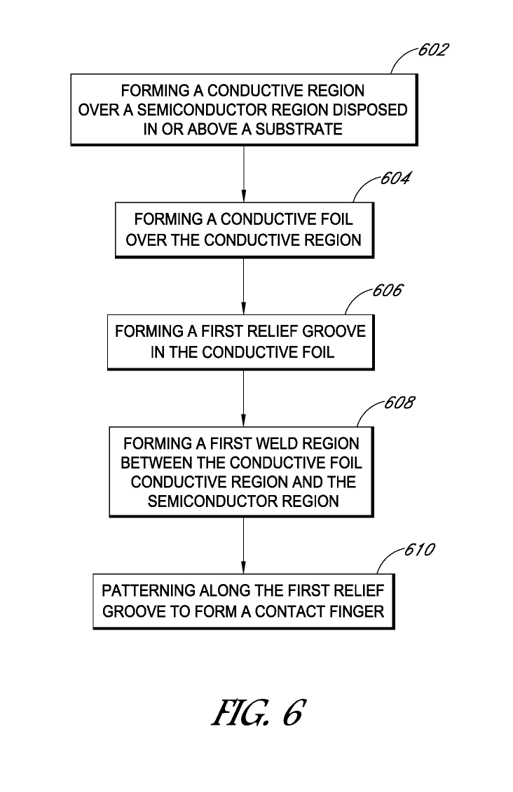

With reference FIG. 6 a flow chart for another method of metallization for a solar cell is shown, according to some embodiments. In various embodiments, the method of FIG. 6 can include additional (or fewer) blocks than illustrated. For example, in some embodiments, forming a conductive region at block 602 may not be performed or (instead) a conductive foil may be formed directly over a semiconductor region at 604. As another example, in some embodiments, the relief groove(s) may be pre-formed before the metallization. In such embodiments, block 606 may not be performed.

As shown in 602, a conductive region can be formed over a semiconductor region disposed in or above a substrate. In an embodiment, the substrate can be a silicon substrate. In some embodiments, the semiconductor region is a polysilicon region. For example, in one embodiment, the first conductive region can be formed as a continuous, blanket deposition of metal. Deposition techniques can include sputtered, evaporated, or otherwise blanket deposited conductive material. In an embodiment, the conductive region is a printed seed metal region. In an example, the conductive region can include forming copper, tin, tungsten, titanium, titanium tungsten, silver, gold, titanium nitride, tantalum nitride, ruthenium, platinum, aluminum and aluminum alloys. In an embodiment before forming the conductive region over the semiconductor region, a damage buffer (e.g., an absorbing or reflecting region) can be formed between respective N-type and P-type regions of the semiconductor region.

At 604, a conductive foil can be formed over the conductive region. In an embodiment, forming the conductive foil can include placing/applying an aluminum and/or an aluminum alloy or other foil over the conductive region. In some embodiments, the conductive foil can be formed directly over the semiconductor region. In some embodiments, the conductive foil can be a textured or smooth foil. In an embodiment, forming the conductive region can include forming an aluminum and/or aluminum alloy foil directly over the semiconductor region (e.g., without an intervening conductive region between the foil and semiconductor region). In various embodiments, conductive foil can include aluminum, copper, tin, other conductive materials, and/or a combination thereof.

At 606, a first relief groove can be formed in the conductive foil. In an embodiment, the first relief groove can be a partial cavity, depression, protrusion, divot, or notch in the conductive foil. In an embodiment, a laser can be applied on the conductive foil to form the first relief groove. In some embodiments a scribing process can be performed to form the first relief groove. In an embodiment, the first relief groove can be formed by scratching or denting a location of the conductive foil. In an embodiment, multiple relief grooves can be formed in the conductive foil. In an embodiment, the relief groove(s) can be formed in a circular shape, in a line or a in a dashed-line (e.g., an example is shown in FIG. 15). In some embodiments, conductive foil can be provided with relief grooves formed before the solar cell metallization process. Although expressly described here as a relief groove, the relief groove can also be any type of relief region. In an example, the relief groove formed can instead be a protrusion region, such as that described in FIGS. 3-5.

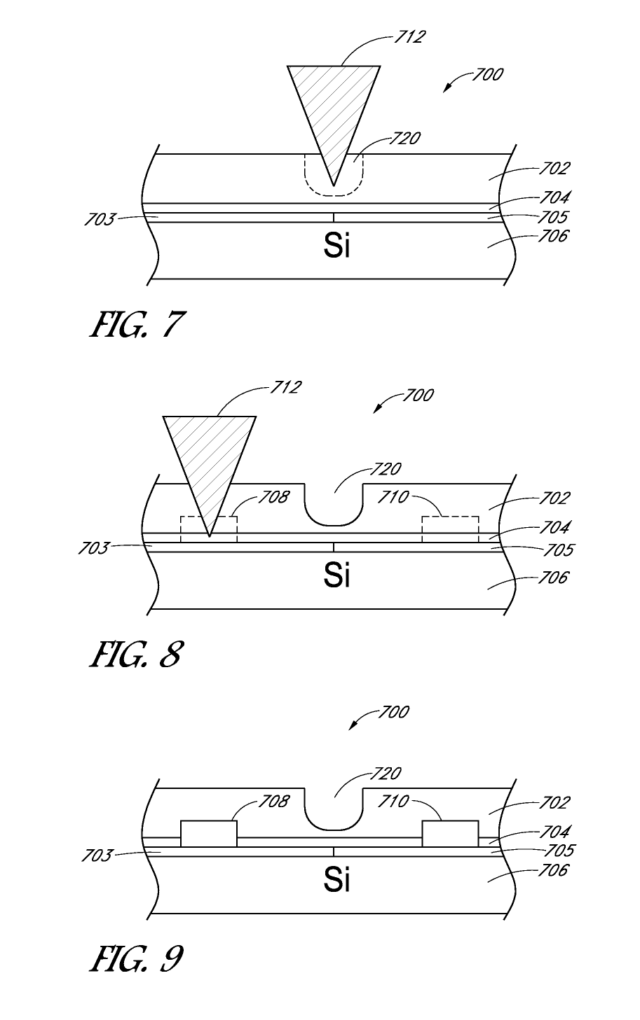

FIGS. 7 and 8 show an example of forming a relief groove.

At 608, a first weld region can be formed between the conductive foil and the conductive region and/or the semiconductor region. In an embodiment, a laser can be used to form the first weld region. The relief groove(s) can release tensile stress of the conductive foil and any compressive stress on the substrate, and thus inhibit the effect of thermal distortion on the solar cell during the formation of the first weld region (e.g., during the welding process).

In an embodiment, the first relief groove can be formed adjacent to at least one weld region. In some embodiments, the first relief groove can be between multiple weld regions. In an embodiment, the weld region(s) can be formed at least partially underneath the first relief groove such that the weld is applied over and through the relief groove. In an embodiment, a laser can be applied over and through the relief groove to form the weld region.

At 610, a contact finger can be formed. In an embodiment, a patterning process can be performed along the first relief groove to form the contact finger. In an embodiment, the patterning can include a grooving process. An example grooving process can include applying a laser along the first relief groove to form opposite polarity contact fingers from the conductive foil. In an example, a grooving process can also include scribing, scratching or denting locations on the conductive foil. In some embodiments, the patterning process can include an etching process. In other embodiments, the patterning process can include both grooving and etching processes, performed together or in separate stages.

In one embodiment, foil may not need to be separately grooved for patterning in a scenario where the relief groove(s) are in locations where patterning is to occur. In such an embodiment, to complete the patterning process, the relief groove(s) may be etched to complete the separation of the fingers.

In an embodiment, the first weld region can couple the contact finger to the semiconductor region.

FIGS. 7-10 illustrate example stages in forming weld region and relief structures on a solar cell. Unless otherwise specified below, the numerical indicators used to refer to components in FIGS. 7-10 are similar to those used to refer to components or features in FIGS. 1 and 2.

FIG. 7 illustrates the formation of a first relief groove in a conductive foil of a solar cell. The solar cell 700 can include a substrate 706. In an embodiment, the substrate 706 can be a silicon substrate. In an embodiment, the silicon substrate 706 can be single-crystalline or multi-crystalline silicon. The solar cell 700 can also include semiconductor regions 703, 705. In some embodiments the semiconductor regions 703, 705 can include a P-type doped semiconductor region 703 and an N-type doped semiconductor region 705. In some embodiments, the substrate 706 can be cleaned, polished, planarized, and/or thinned or otherwise processed before the formation of semiconductor regions 703, 705. In an example, the conductive region can include copper, tin, tungsten, titanium, titanium tungsten, silver, gold, titanium nitride, tantalum nitride, ruthenium, platinum, aluminum and/or aluminum alloys. In some embodiments, the conductive foil 702 can include aluminum, aluminum alloy, copper, nickel, tin, and/or alloys of any of those materials, among other examples. In an embodiment, the conductive foil 702 can be a textured or smooth foil. In an embodiment, the conductive foil 702 can be formed directly over the semiconductor regions 703, 705.

In an embodiment, a laser 712 can be applied to the conductive foil 702 to form the first relief groove 720. In some embodiments, a scribing process can be performed to form the first relief groove 720. In an embodiment, the first relief groove 720 can be formed by scratching or denting a location of the conductive foil 702. In an embodiment, a relief groove can be a partial cavity, depression or notch in the conductive foil 702. The first relief groove 720 can release tensile stress of the conductive foil 702 and/or any compressive stress on the substrate 706, and thus inhibit the effect of thermal distortion on the solar cell 700 during a welding process. The first relief groove 720 can also reduce stress between the conductive foil 702 and the conductive region 704. In an embodiment, the conductive foil 702 can include multiple relief grooves. In an embodiment, the relief groove(s) can be formed in a circular shape, in a line or a in a dashed-line (e.g., an example is shown in FIG. 15). In some embodiments, conductive foil 702 can be provided with relief grooves formed before the solar cell metallization process.

With reference to FIG. 8, forming weld regions on a solar cell is shown, according to some embodiments. A laser 712 can be applied to form first and second weld regions 708, 710. In an embodiment, the first and second weld regions 708, 710 allow for conduction of electricity between the semiconductor regions 703, 705, conductive region 704 (if present), and conductive foil 702. In some embodiments, the first relief groove 720 can be formed adjacent to weld regions 708, 710, as shown.

FIG. 9 illustrates an example solar cell subsequent to the welding process of FIG. 8. In an embodiment, the first relief groove 720 can be formed adjacent to at least one weld region. In an embodiment, the first relief groove 720 can be formed between weld regions 708, 710 as shown.

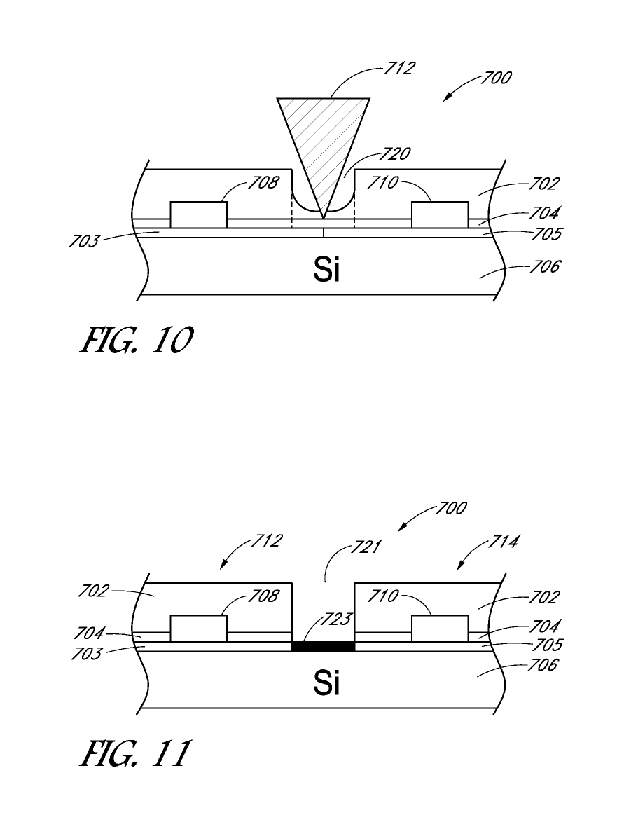

With reference to FIG. 10, patterning along the first relief groove to form a contact finger is illustrated, according to various embodiments. In an embodiment, a laser 712 can be applied along the first relief groove 720 to form contact fingers. In some embodiments, a scribing process can be performed along the first relief groove 720 to form the contact fingers. In an embodiment, a scratching or denting can be performed along the first relief groove 720 to form the contact fingers. In an embodiment, the patterning can include any number of grooving processes (e.g., applying a laser, scribing, scratching, denting, etc.). In some embodiments, the patterning process can also include an etching along the first relief groove 720. In other embodiments, the patterning process can include both grooving and etching processes, performed together or in separate stages.

FIGS. 11-14 illustrate example solar cells fabricated using the method of FIG. 6. Unless otherwise specified below, the numerical indicators used to refer to components in FIGS. 11-14 are similar to those used to refer to components or features in FIGS. 6-10.

FIG. 11 illustrates an example solar cell subsequent to the method of FIG. 6. A conductive foil 702 can be disposed over a conductive region 704. A conductive region 704 can be disposed over semiconductor regions 703, 705, with the conductive foil 702 disposed over conductive region 704. In some embodiments, the conductive foil 702 can be disposed directly over the semiconductor regions 703, 705 without the conductive region 704.

In an embodiment, the substrate 706 is a silicon substrate. The solar cell 700 can also include first and second contact fingers 712, 714. In some embodiments the semiconductor regions 703, 705 can include a P-type doped semiconductor region 703 and an N-type doped semiconductor region 705. A trench region 721 can be disposed between the P-type doped semiconductor region 703 and an N-type doped semiconductor region 705, where the trench region 721 separates doped semiconductor regions of opposite polarity.

In some embodiments, an absorbing (or reflecting) region 723 can be disposed in the trench region 721 and between the N-type and P-type doped semiconductor regions 703, 705 to protect the substrate 706 from damage during the patterning process. In an embodiment, the absorbing region 723 can be formed before forming a conductive region and conductive foil (e.g., before performing 302 and 306 and before forming a relief groove in FIG. 7).

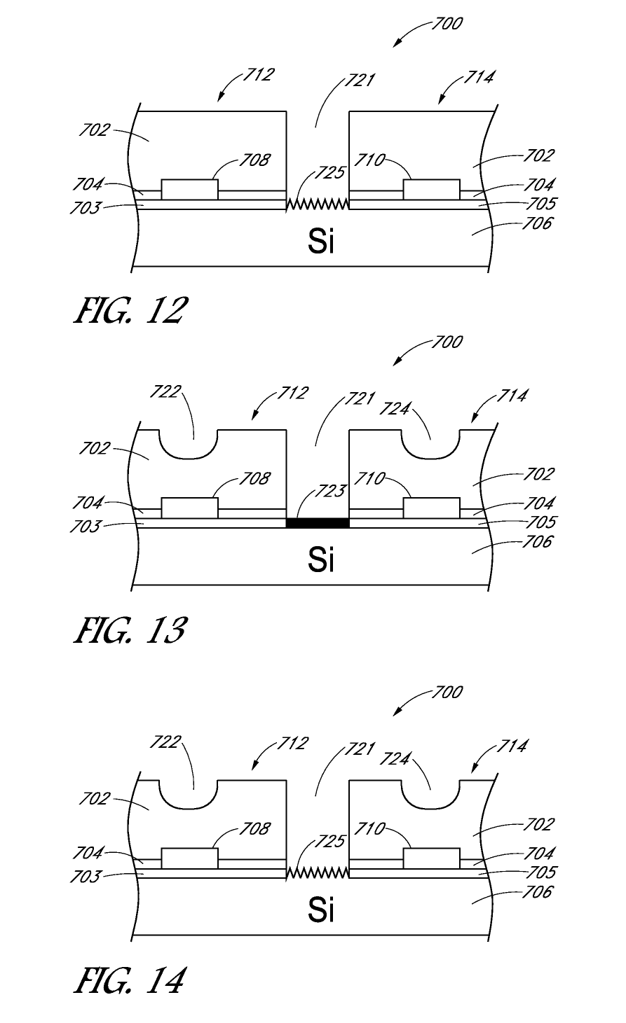

With reference to FIG. 12, another example solar cell subsequent to the method of FIG. 6 is shown. A conductive foil 702 can be disposed over a conductive region 704. A conductive region 704 can be disposed over semiconductor regions 703, 705 with conductive foil 702 disposed over the conductive region 704. In some embodiments, the conductive foil 702 can be disposed directly over the semiconductor regions 703, 705 without the conductive region 704. In an embodiment, the substrate 706 is a silicon substrate. The solar cell can include first and second contact fingers 712, 714. In some embodiments the semiconductor regions 703, 705 can include a P-type doped semiconductor region 703 and an N-type doped semiconductor region 705. A trench region 721 can be formed between the P-type doped semiconductor region 703 and an N-type doped semiconductor region 705, where the trench region 721 separates doped semiconductor regions of opposite polarity. A texturized region 725 can be formed at the trench region 721 and between the N-type and P-type doped semiconductor regions 703, 705, where the texturized region 725 can allow for additional light absorption. In some embodiments, there need not be a texturized region 725 within the trench region 721. In some embodiments, a trench region 721 may not be present, where the P-type doped semiconductor region 703 can be adjacent to an N-type doped semiconductor region 705.

FIG. 13 illustrates still another example solar cell subsequent to the method of FIG. 6. A conductive foil 702 can be disposed over a conductive region 704. A conductive region 704 can be disposed over semiconductor regions 703, 705. In some embodiments, the conductive foil 702 can be disposed directly over the semiconductor regions 703, 705 without the conductive region 704. In an embodiment, the substrate 706 is a silicon substrate. A first and second contact finger 712, 714 can be formed. In some embodiments the semiconductor regions 703, 705 can include a P-type doped semiconductor region 703 and an N-type doped semiconductor region 705. In an embodiment, a first and second weld regions 708, 710 can be formed at least partially underneath a first and second relief grooves 722, 724. In an embodiment, a single and/or multiple weld regions can be formed at least partially underneath a single and/or multiple relief grooves, respectively. A trench region 721 can be formed between the P-type doped semiconductor region 703 and an N-type doped semiconductor region 705. An absorbing region 723 can be formed at the trench region 721 and between the N-type and P-type doped semiconductor regions 703, 705 to protect the substrate 706 from damage during the patterning process of FIG. 10.

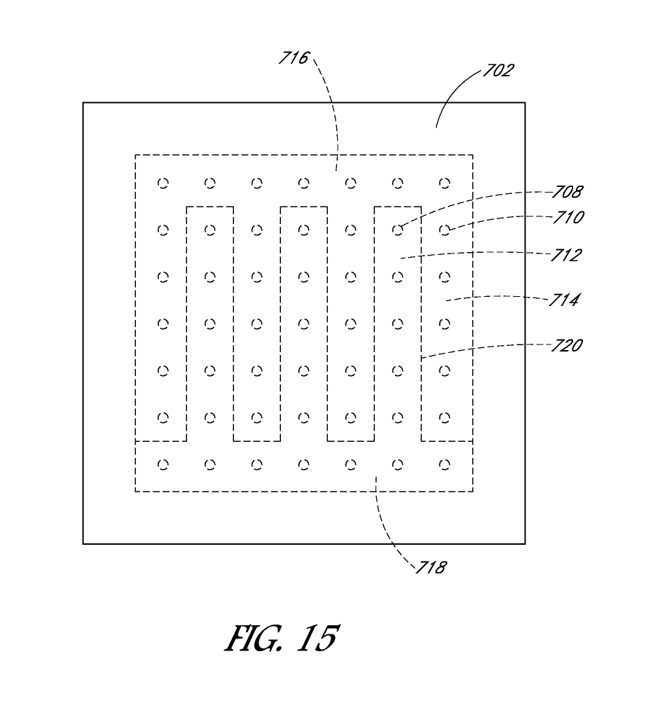

With reference to FIG. 14, yet another example solar cell subsequent to the method of FIG. 6 is shown. A conductive foil 702 can be disposed over a conductive region 704. A conductive region 704 can be disposed over semiconductor regions 703, 705, with conductive foil 702 disposed over conductive region 704. In some embodiments, the conductive foil 702 can be formed directly over the semiconductor regions 703, 705 without the conductive region 704.

In an embodiment, the substrate 706 is a silicon substrate. The solar cell can also include first and second contact fingers 712, 7214. In some embodiments the semiconductor regions 703, 705 can include a P-type doped semiconductor region 703 and an N-type doped semiconductor region 705. In an embodiment, first and second weld regions 708, 710 can be formed at least partially underneath the first and second relief grooves 722, 724. A trench region 721 can be disposed between the P-type doped semiconductor region 703 and an N-type doped semiconductor region 705, where the trench region 721 separates doped semiconductor regions of opposite polarity. A texturized region 725 can be formed at the trench region 721 and between the N-type and P-type doped semiconductor regions 703, 705, where the texturized region 725 can allow for additional light absorption. In some embodiments, there need not be a texturized region 725 within the trench region 721. In some embodiments, a trench region 721 may not be present, where the P-type doped semiconductor region 703 can be adjacent to an N-type doped semiconductor region 705.

FIG. 15 illustrates a schematic plan view of a conductive foil formed over a solar cell during steps 602-608 of FIG. 6. FIG. 15 also illustrates a schematic plan view of the conductive foil during the stages of solar cell metallization shown in FIGS. 7 and 8. The conductive foil 702 can have first and second busbar regions 718, 716 respectively. In an embodiment, the first and second busbar regions 718, 716 can be positive or negative busbar regions. A number of weld regions, such as weld regions 708 and 710 are also shown. Relief grooves 720 are shown in dashed-lines. In an embodiment, the relief grooves 720 can also be formed in a line. First and second contact fingers 712, 714 are also shown.

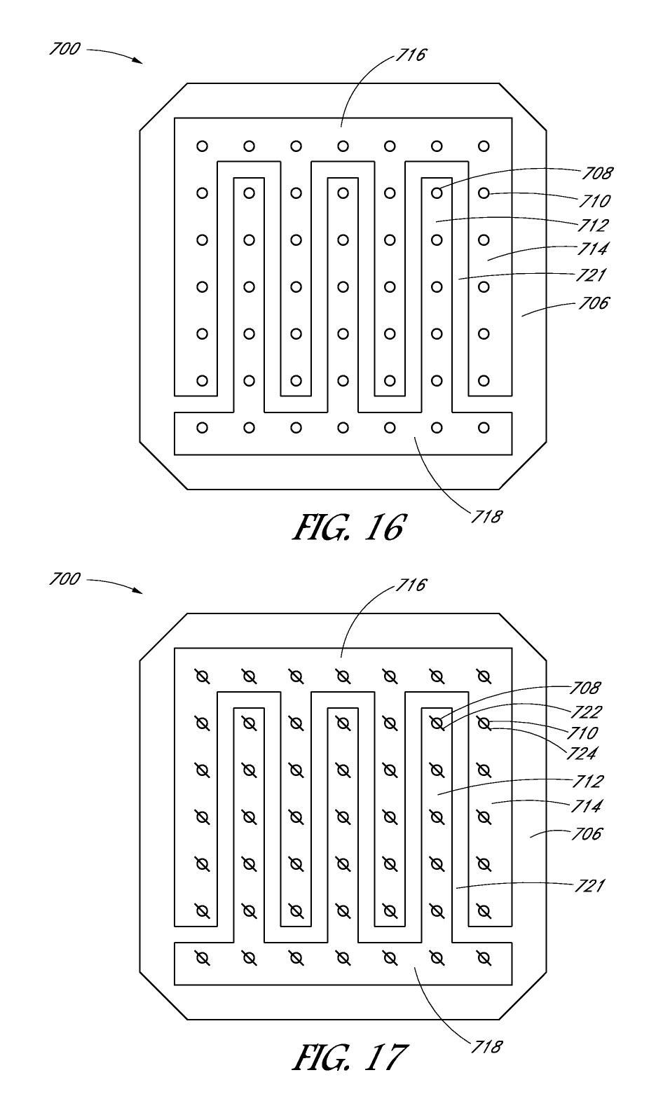

With reference to FIG. 16, a schematic plan view of an example solar cell is shown. Unless otherwise specified, the numerical indicators used to refer to components in FIG. 16 are similar to those used to refer to components or features in FIGS. 11 and 12. The solar cell 700 can include first and second metal contact regions. The first metal contact region can include a first busbar region 718 and first contact finger 712. The second metal contact region can include a second busbar region 716 and second contact finger 714. In an embodiment, the first busbar region 718 and the first contact finger 712 can have a positive polarity. In an embodiment, the second busbar 716 and second contact finger 714 can have a negative polarity. The metal regions can be formed over a substrate 706. The substrate 706 can be a silicon substrate. A semiconductor region can be formed over the substrate 706. Weld regions 708, 710 can be formed in the first and second contact fingers 712, 714. A trench region 721 can be formed between first and second contact fingers 712, 714. In an embodiment, the trench region 721 can have an absorbing region as shown in FIG. 11. In an embodiment, the trench region 721 can be texturized or non-texturized as described in FIG. 12. In some embodiments, there need not be a trench region.

FIG. 17 illustrates a schematic plan view of another example solar cell. Unless otherwise specified, the numerical indicators used to refer to components in FIG. 17 are similar to those used to refer to components or features in FIGS. 13 and 14. The solar cell 700 can include first and second metal contact regions. The first metal contact region can include a first busbar region 718 and first contact finger 712. The second metal contact region can include a second busbar region 716 and second contact finger 714. In an embodiment, the first busbar region 718 and the first contact finger 712 can have a positive polarity. In an embodiment, the second busbar 716 and second contact finger 714 can have a negative polarity. The metal regions can be formed over a substrate 706. The substrate 706 can be a silicon substrate.

A first and second weld region 708, 710 can be formed in the first and second contact fingers 712, 714 respectively, where the weld regions 708, 710 are formed at least partially underneath a first and second relief grooves 722, 724. In an embodiment, multiple weld regions and relief grooves can be formed.

In some embodiments, the relief grooves can be adjacent to the weld regions, can be formed in an alternate pattern between weld regions, may not be in-line with the weld regions, and/or may not have a one-to-one correspondence between relief grooves and weld regions.

Also, a trench region 721 can be formed between the first and second contact fingers 712, 714. In an embodiment, the trench region 721 can have an absorbing region as shown in FIG. 13. In an embodiment, the trench region 721 can be texturized or non-texturized as described in FIG. 14. In some embodiments, there need not be a trench region. In an embodiment, the first and second relief grooves 722, 724 can be formed in various shapes such as in lines or dashed-lines. In some embodiments, the direction of relief groove lines can be perpendicular, parallel or diagonal to the direction the trench region 721 is formed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A solar cell, comprising:
a semiconductor region disposed in or above a substrate;
a contact finger formed over the semiconductor region, wherein a first weld region couples the contact finger to the semiconductor region; and
a first relief groove formed in the contact finger.

2. The solar cell of claim 1, wherein the first weld region is formed at least partially underneath the first relief groove.

3. The solar cell of claim 1, wherein the first relief groove comprises a circular shape or a line.

4. The solar cell of claim 1, wherein a second weld region also couples the contact finger to the semiconductor region.

5. The solar cell of claim 1, further comprising a second relief groove formed in the contact finger.

6. The solar cell of claim 5, wherein the first and second relief grooves comprise a dashed-line.

7. The solar cell of claim 1, wherein the contact finger comprises a foil that includes aluminum or aluminum alloys.

8. The solar cell of claim 1, further comprising an absorbing region disposed between respective N-type and P-type doped regions of the semiconductor region.

9. The solar cell of claim 1, further comprising a conductive region coupled to and between the contact finger and the semiconductor region.

10. The solar cell of claim 9, wherein the conductive region comprises a metal selected from the group containing copper, tin, tungsten, titanium, titanium tungsten, silver, gold, titanium nitride, tantalum nitride, ruthenium, platinum, aluminum, and aluminum alloys.

11. A method of metallization for a solar cell, the method comprising:
forming a conductive foil over a semiconductor region disposed in or above a substrate;
forming a first relief groove in the conductive foil; and
forming a first weld region between the conductive foil and the semiconductor region.

12. The method of claim 11, further comprising before forming a conductive foil, forming a conductive region over the semiconductor region.

13. The method of claim 11, wherein forming the first relief groove comprises applying a laser to a location of the conductive foil to form the first relief groove.

14. The method of claim 11, further comprising forming an absorbing region between respective N-type and P-type doped regions of the semiconductor region.

15. The method of claim 11, further comprising patterning the first relief groove to form a contact finger.

16. The method of claim 15, further comprising etching the first relief groove to form a contact finger.

17. A method of metallization for a solar cell, the method comprising:
forming a conductive region over a semiconductor region disposed in or above a substrate;
forming a conductive foil over the conductive region;
forming a first relief groove in the conductive foil; and
forming a first weld region between the conductive foil and the conductive region, wherein the first weld region is formed at least partially underneath the first relief groove.

18. The method of claim 17, wherein forming the first relief groove comprises scribing a location of the conductive foil to form the first relief groove.

19. The method of claim 17, further comprising patterning the first relief groove to form a contact finger.

20. The method of claim 17, further comprising etching the first relief groove to form a contact finger.
